(19) United States
(12) Patent Application Publication
(10) Pub. No.: US 2007/0217473 A1
(43) Pub. Date: Sep. 20, 2007

(54) Laser equipment

(75) Inventors: Katsunori Abe, Chita-gun (JP); Nobuyuki Otake, Nukata-gun (JP)

Correspondence Address: POSZ LAW GROUP, PLC, 12040 SOUTH LAKES DRIVE, SUITE 101, RESTON, VA, 20191, US

(73) Assignee: DENSO CORPORATION, Kariya-city (JP)

(21) Appl. No.: 11/641,111

(22) Filed: Dec. 19, 2006

(30) Foreign Application Priority Data
Dec. 20, 2005 (JP) 2005-366898

(51) Int. Cl. H01S 5/00

(52) U.S. Cl. 372/50.124; 372/50.23

(57) ABSTRACT

A laser equipment includes: a surface emitting laser for emitting an excitation light; a light converter for outputting an output light by receiving the excitation light; and a lens portion for collimating or concentrating a light. The surface emitting laser has an emitting surface for emitting the excitation light, and the light converter has an input surface for receiving the excitation light and an output surface for outputting the output light. The surface emitting laser, the light converter and the lens portion are integrally stacked so that the lens portion is disposed between the emitting surface of the surface emitting laser and the input surface of the light converter or disposed on the output surface of the light converter.

### CROSS REFERENCE TO RELATED APPLICATION

This application is based on Japanese Patent Application No. 2005-366898 filed on Dec. 20, 2005, the disclosure of which is incorporated herein by reference.

### FIELD OF THE INVENTION

The present invention relates to a laser equipment.

### BACKGROUND OF THE INVENTION

Devices each of which has a configuration wherein excitation light is converted into light of different wavelength so as to output the resulting light have been known as disclosed in, for example, JP-A-2004-134633, JP-A-2005-20002 (corresponding to U.S. Pat. No. 6,879,618) and JP-A-2001-237488 (corresponding to U.S. Pat. No. 6,693,941).

The device stated in JP-A-2004-134633 is such that a phosphor layer is excited with excitation light which is outputted from a flat emission laser, and that light which is different in wavelength from the excitation light is outputted.

The device stated in U.S. Pat. No. 6,879,618 is such that an organic active layer which constitutes a vertical laser resonator is excited with excitation light which is outputted from an organic light-emitting diode, and that laser light which is different in wavelength from the excitation light is outputted.

The device stated in U.S. Pat. No. 6,693,941 is such that a flat emission type semiconductor element is excited with excitation light which is outputted from a semiconductor laser element, and that the wavelength of the emission light of the flat emission type semiconductor element is converted by a wavelength conversion element so as to output laser light of ultraviolet region.

In case of the device stated in JP-A-2004-134633, the light which is outputted from the phosphor layer is natural emission light (incoherent light). That is, a light beam condensability which is equivalent to that of laser light (coherent light) cannot be obtained as the output light. Accordingly, the device is unsuited to a light source for a high-resolution display.

In case of the configuration stated in U.S. Pat. No. 6,879,618, the organic light-emitting diode which outputs incoherent light is employed as an excitation light source, and the laser light is emitted in such a way that the incoherent light is absorbed by a host material in the organic active layer, whereupon excitation energy is caused to migrate to a dopant. Accordingly, the efficiency of conversion into the laser light is low, and light of high power cannot be obtained.

In case of the configuration stated in U.S. Pat. No. 6,693,941, the flat emission type semiconductor element needs to be excited using the separate semiconductor laser element. Besides, the individual constituents of the device are arranged in spaced fashion. Accordingly, the device is not suited to reduction in size.

### SUMMARY OF THE INVENTION

In view of the above-described problem, it is an object of the present disclosure to provide a laser equipment.

According to an aspect of the present disclosure, a laser equipment includes: a surface emitting laser for emitting an excitation light, wherein the surface emitting laser includes a pair of first reflection layers and an activation layer disposed between the pair of first reflection layers; a light converter for outputting an output light by receiving the excitation light, wherein the output light has a peak wavelength, which is different from a peak wavelength of the excitation light, and wherein the light converter includes a pair of second reflection layers and a solid laser medium layer disposed between the pair of second reflection layers; and a lens portion for collimating or concentrating a light. The surface emitting laser has an emitting surface for emitting the excitation light, and the light converter has an input surface for receiving the excitation light and an output surface for outputting the output light, and the surface emitting laser, the light converter and the lens portion are integrally stacked so that the lens portion is disposed between the emitting surface of the surface emitting laser and the input surface of the light converter or disposed on the output surface of the light converter.

In the above equipment, the dimensions of the equipment become small. Further, a distance between the surface emitting laser and the light converter, specifically, between the activation layer and the solid laser medium layer, is reduced, so that energy loss of the excitation light is reduced, and further, the equipment can output the output light with high power. Furthermore, since the equipment includes the surface emitting laser and the solid laser medium layer, energy conversion efficiency of the equipment is high, so that the equipment can output the output light with high power. When the lens portion is disposed between the emitting surface of the surface emitting laser and the input surface of the light converter, the solid laser medium layer is effectively excited, so that the equipment can output the output light with high power. When the lens portion is disposed on the output surface of the light converter, the beam shape of the output light can be controlled by the lens portion effectively.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional view showing a laser equipment according to a first embodiment;

FIG. 2 is a schematic chart showing excitation and transition in a solid laser medium layer;

FIG. 3 is a cross sectional view showing a laser equipment according to a second embodiment;

FIG. 4 is a cross sectional view showing a laser equipment according to a modification of the second embodiment;

FIG. 5 is a partially enlarged cross sectional view showing a laser equipment according to a third embodiment;

FIG. 6 is a partially enlarged cross sectional view showing a laser equipment according to a modification of the third embodiment;

FIG. 7 is a partially enlarged cross sectional view showing a laser equipment according to a fourth embodiment;

FIG. 8 is a partially enlarged cross sectional view showing a laser equipment according to a fifth embodiment;

FIG. 9 is a partially enlarged cross sectional view showing a second reflection layer in the laser equipment;

FIG. 10 is a graph showing a relationship between a wavelength and a reflectivity;

FIG. 11 is a graph showing a relationship between a difference of refraction index and a reflection bandwidth;

FIG. 12 is a perspective view showing an arrangement of regions 1-3 in a laser equipment according to a first modification of the fifth embodiment;

FIG. 13 is a plan view showing another arrangement of the regions 1-3 in a laser equipment according to a second modification of the fifth embodiment;

FIG. 14 is a partially enlarged cross sectional view showing a laser equipment according to a sixth embodiment;

FIG. 15 is a partially enlarged cross sectional view showing a laser equipment according to a seventh embodiment;

FIG. 16 is a partially enlarged cross sectional view showing a laser equipment according to a modification of the seventh embodiment;

FIG. 17 is a partially enlarged cross sectional view showing a laser equipment according to an eighth embodiment;

FIG. 18 is a partially enlarged cross sectional view showing a laser equipment according to a ninth embodiment;

FIG. 19 is a partially enlarged cross sectional view showing a laser equipment according to a first modification of the ninth embodiment; and

FIG. 20 is a partially enlarged cross sectional view showing a laser equipment according to a second modification of the ninth embodiment.

### DETAILED DESCRIPTION OF THE PREFERRED EMBODIMENTS

### First Embodiment

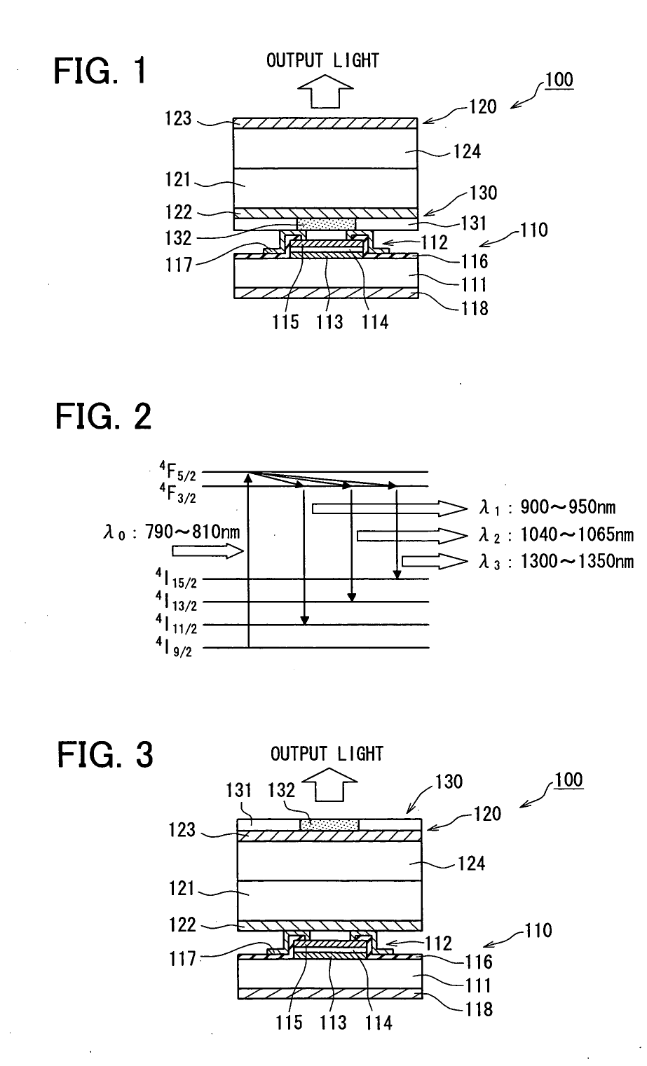

FIG. 1 is a sectional view showing the schematic configuration of a laser device according to the first embodiment. As shown in FIG. 1, the laser device 100 includes a flat emission laser 110 which serves as an excitation light source, a light emission unit 120 which receives excitation light and which outputs any of laser lights of different wavelengths, and a lens member 130 which collimates or condenses an inputted light beam.

The flat emission laser 110 has a light emitting element 112 formed on a semiconductor substrate 111, and it is configured so as to output the excitation light in a direction substantially perpendicular to the plane of the semiconductor substrate 111. A known configuration can be adopted as the configuration of the flat emission laser 110. This embodiment is configured so that the laser light which is outputted from the device 100 may become visible lights of desired colors.

Concretely, an n-GaAs substrate is adopted as the semiconductor substrate 111, and a multilayer reflection film 113 of Al_{z1}Ga_{1-z1}As/Al_{z2}Ga_{1-z2}As (0≦z1<z2≦1) doped with an n-type dopant (for example, Se) is formed on one surface of the semiconductor substrate 111. The multilayer reflection film 113 in which the Al_{z1}Ga_{1-z1}As layer and the Al_{z2}Ga_{1-z2}As layer are stacked is one of first reflection layers, and it shall be hereinbelow termed the “first reflection layer 113”.

A clad layer of AlGaAs (not shown), a multiple quantum well layer 114 of Alₓ₁In_{y1}Ga_{1-x1-y1}AS/Alₓ₃In_{y3}Ga_{1-x3-y3}As and a clad layer of AlGaAs (not shown) are successively stacked on the first reflection layer 113. The multiple quantum well layer 114 in which the Alₓ₁In_{y1}Ga_{1-x1-y1}As layer and the Alₓ₃In_{y3}Ga_{1-x3-y3}As layer are stacked is an active layer, and it shall be hereinbelow termed the “active layer 114”. The composition and thickness of the active layer 114 are adjusted so as to output laser light (the excitation light) having a desired emission wavelength. The active layer 114 is formed so that its optical thickness may become one wavelength. In this embodiment, the optical thickness is adjusted so that the emission wavelength may be included within a range of 790-810 nm (for example, it may become 808 nm).

A multilayer reflection film 115 of Al_{z3}Ga_{1-z3}As/Al_{z4}Ga_{1-z4}As (0≦z3<z4≦1) doped with a p-type dopant is formed on the clad layer of AlGaAs. The multilayer reflection film 115 in which the Al_{z3}Ga_{1-z3}As layer and the Al_{z4}Ga_{1-z4}As layer are stacked is the other of the first reflection layers, and it shall be hereinbelow termed the “first reflection layer 115”.

Incidentally, the thickness of each of the respective layers which constitute the first reflection layer 113 or 115 having the multilayer structure is set at a value which is obtained by dividing the emission wavelength by the quadruple of a refractive index. The refractive index is adjusted so that the first reflection layer 113 may become greater in reflection factor than the first reflection layer 115 with respect to the laser light (excitation light) which is outputted from the active layer 114. That is, the laser device is configured so that the excitation light outputted from the active layer 114 may be resonated by the first reflection layers 113 and 115 and then lased onto the side of the first reflection layer 115.

Each of the individual layers mentioned above can be formed by employing a known crystal growth method such as MOCVD (mietallorganic chemical vapor deposition) or MBE (molecular beam epitaxy). In addition, the crystal growth steps of the individual layers are followed by processes such as mesa etching and insulating-film formation for isolating the element, and electrode-film evaporation, whereby the light emitting element 112 is configured. That is, the flat emission laser 110 is configured with the light emitting element 112 arranged on the semiconductor substrate 111.

By the way, in FIG. 1, numeral 116 designates an insulating film (silicon oxide film in this embodiment) for insulatingly isolating the films 113-115 and for narrowing down light and current in a horizontal direction (the direction of the plane of the substrate). Numeral 117 designates a p-type electrode (of Cr/Pt/Au in this embodiment), and numeral 118 an n-type electrode (of Au—Ge/Ni/Au in this embodiment).

The light emission unit 120 includes, at least, a solid laser medium layer 121, and second reflection layers 122 and 123 which are respectively arranged on the excitation-light input surface and output surface of the solid laser medium layer 121.

Concretely, an Nd:YAG (Y₃Al₅O₁₂) crystal is adopted as the constituent material of the solid laser medium layer 121. When the solid laser medium layer 121 receives the excitation light which is outputted from the flat emission laser 110 (light emitting element 112) and whose emission wavelength λ₀ is adjusted within the range of 790-810 nm as stated above, electrons are selectively excited at the transition of the energy levels ⁴I_{9/2} →⁴F_{5/2} of Nd ions with which the YAG crystal is doped, as shown in FIG. 2. At the transition ⁴I_{9/2}→⁴F_{5/2}, absorption is much, and an efficient excitation is possible. Incidentally, FIG. 2 is a model diagram showing the excitation and the transition in the solid laser medium layer 121.

As shown in FIG. 2, the electrons excited to the energy level ⁴F_{5/2} are once transmitted to an energy level ⁴F_{3/2} by non-radiation relaxation which does not accompany light emission, and they are thereafter transmitted to energy levels ⁴I_{11/2}, ⁴I_{13/2} and ⁴I_{15/2}, respectively. Simultaneously with the transitions, laser lights which have peak wavelengths λ₁, λ₂ and λ₃ within ranges of 900-950 nm (946 nm in this embodiment), 1040-1065 nm (1064 nm in this embodiment) and 1300-1350 nm (1319 nm in this embodiment) are respectively generated in accordance with the wavelength λ₀ of the excitation light. That is, the plurality of lights of the different peak wavelengths are generated from the identical solid-laser-medium layer 121 irradiated with the excitation light.

The second reflection layers 122 and 123 are configured so as to selectively resonate and laser with one peak wavelength among the plurality of lights of the different peak wavelengths generated by the irradiation with the excitation light. In this embodiment, a multilayer reflection film of Al₂O₃/TiO₂ formed by a technique such as evaporation or sputtering is adopted as the configuration of each of the second reflection layers 122 and 123, and the thickness of each of the layers (Al₂O₃ layer and TiO₂ layer) is set at a value obtained by dividing the resonance wavelength by the quadruple of a refractive index. Besides, the reflection factors of the second reflection layers 122 and 123 are set so as to become lower in the second reflection layer 123 of output side than in the second reflection layer 122 of excitation-light input side. Accordingly, the light (laser light) having the single wavelength can be outputted from the side of the second reflection layer 123.

Further, the light emission unit 120 according to this embodiment includes a wavelength conversion layer 124 which is stacked and arranged on the output surface of the solid laser medium layer 121, and which subjects the above peak wavelength to wavelength conversion. Owing to such provision of the wavelength conversion layer 124, it is permitted to output laser light having a desired wavelength as cannot be obtained with only the solid laser medium layer 121. Incidentally, although the wavelength conversion layer 124 is stacked and arranged on the output surface of the solid laser medium layer 121 here, it may well be stacked and arranged on the second reflection layer 123 which is stacked and arranged on the output surface of the layer 121. In either of the cases, the wavelength conversion layer 124 is unitarily stacked and arranged, so that the laser device 100 can be reduced in size. In this embodiment, the wavelength conversion layer 124 is stacked and arranged on the output surface of the solid laser medium layer 121 as shown in FIG. 1.

Besides, in this embodiment, a nonlinear crystal which generates the second harmonic of the peak wavelength is adopted as the constituent material of the wavelength conversion layer 124. As the nonlinear crystal, a known one can be properly selected and employed in accordance with the wavelength which is inputted. There is, for example, KTP(KTiOPO₄), LBO(LiB₃O₅), BiBO(BiB₃O₆), PPLTP (Periodically Poled KTP), or the like. The nonlinear crystal KTP is adopted in this embodiment.

Accordingly, the near-infrared light, which is generated from the Nd ions and which is selectively resonated and lased by the second reflection layers 122 and 123, can be converted into the visible light (laser light) by the wavelength conversion layer 124 so as to output the resulting light from the light emission unit 120. That is, the laser device 100 can be utilized as a light source for RGB use. By the way, in this embodiment, the lights having the above peak wavelengths λ₁, λ₂ and λ₃ can be converted by the wavelength conversion layer 124 into lights having wavelengths within ranges of 450-475 nm (blue), 520-533 nm (green) and 650-675 nm (red) as are visible lights. That is, laser lights in three primary colors of R, G and B can be obtained, depending upon the configuration of the second reflection layers 122 and 123.

The lens member 130 condenses or collimates the beam of the light inputted as stated before. In this embodiment, the lens member 130 is interposed between the flat emission laser 110 and the light emission unit 120, and it is configured so as to condense or collimate the beam of the excitation light. That is, the lens member 130 is configured so that the solid laser medium layer 121 may be efficiently excited by the condensed or collimated excitation light beam. Accordingly, a laser-light conversion efficiency relative to input power can be enhanced, and the output light from the device 100 can be heightened in power.

The lens member 130 adopted is, for example, one in which photolithography and ion diffusion are applied to a base material 131 made of glass, thereby to afford a refractive index distribution and to configure a micro lens 132 of flat plate type. Besides, the micro lens 132 is formed at that part of the base material 131 which corresponds to the light emitting element 112, in a positioned state (in other words, at a part at which the optic axis of the excitation light outputted from the light emitting element 112 is substantially in agreement with the optic axis of the micro lens 132), and the diameter of this micro lens 132 is made equal to or larger than the diameter (exit aperture) of the light emitting element 112. Accordingly, the efficiency of the collimation or condensation can be enhanced.

In addition, the lens member 130 is stacked and arranged on the excitation-light output surface (in this embodiment, the side of the p-type electrode 117) of the flat emission laser 110, and the light emission unit 120 is stacked and arranged on the lens member 130 with the second reflection film 122 located below. The flat emission laser 110 and the lens member 130, and the lens member 130 and the light emission unit 120 are respectively bonded by a known bonding method (for example, adhesion), whereby the flat emission laser 110, light emission unit 120 and lens member 130 are joined unitarily.

In this manner, in accordance with the laser device 100 according to this embodiment, the flat emission laser 110 is adopted as the excitation light source which generates the excitation light, the light emission unit in which the solid laser medium layer 121 is interposed between the second reflection layers 122 and 123 is adopted as the light emission unit 120 which generates any of the laser lights of the different wavelengths by receiving the excitation light, and the lens member in which the flat plate type micro lens 132 is disposed in correspondence with the light emitting element 112 is adopted as the lens member 130. Accordingly, the respective elements 110, 120 and 130 can be unitarily stacked. That is, the setup of the device can be made small. Besides, owing to the unitary stacking, the distance between the light emitting element 112 (active layer 114) and the light emission unit 120 (solid laser medium layer 121) is shortened. That is, the loss of the excitation light can be decreased to heighten the output power.

Besides, since the longitudinal mode control of the excitation light is performed by the flat emission laser 110, the solid laser medium layer 121 can be directly excited between the energy levels of rare-earth ions or transition-metal ions with which this layer 121 is doped. Accordingly, the energy conversion efficiency is high, and the output power can be heightened. Further, in this embodiment, the excitation light beam condensed or collimated by the lens member 130 is inputted to the light emission unit 120, so that the output power can be heightened more.

Besides, the laser device 100 according to this embodiment is suitable as the RGB light source because the wavelength conversion layer 124 generating the second harmonic is included in the light emission unit 120. It is also allowed, however, to adopt a configuration in which the light emission unit 120 does not include the wavelength conversion layer 124.

Incidentally, this embodiment has mentioned the example in which the multiple quantum well layer 114 of Alₓ₁In_{y1}Ga_{1-x1-y1}AS/Alₓ₃In_{y3}Ga_{1-x3-y3}As is adopted as the active layer 114 constituting the light emitting element 112, while the Nd:YAG crystal is adopted as the solid laser medium layer 121. However, the constituent materials of the active layer 114 and the solid laser medium layer 121 can be properly selected and adopted in accordance with the wavelength which is outputted from the device 100. By way of example, a multiple quantum well layer of Inₓ₂Ga₁₋ₓ₂As_{y2}P_{1-y2}/Inₓ₄Ga₁₋ₓ₄As_{y4}P_{1-y4} can be adopted as the active layer 114. Besides, any of YAG, YVO (YVO₄), GVO (GdvO₄), GGO (Gd₃Ga₅O₁₂), SVAP (Sr₅(VO₄)₃F), FAP ((PO₄)₃F), SFAP (Sr₅(PO₄)₃F), YLF (YLiF₄), etc. which are doped with rare-earth ions or transition-metal ions can be adopted as the solid laser medium layer 121.

### Second Embodiment

Next, the second embodiment will be described in conjunction with FIG. 3. FIG. 3 is a sectional view showing the schematic configuration of a laser device 100 according to the second embodiment.

The laser device 100 according to the second embodiment is common to the laser device 100 illustrated in the first embodiment, at many parts.

As shown in FIG. 3, this embodiment features that a lens member 130 is stacked and arranged on the output surface of a light emission unit 120. More specifically, a flat emission laser 110 and the light emission unit 120, and the light emission unit 120 and the lens member 130 are respectively bonded by a known bonding method (for example, adhesion), whereby the flat emission laser 110, light emission unit 120 and lens member 130 are joined unitarily.

Incidentally, also in this embodiment, the lens member 130 adopted is, for example, one in which photolithography and ion diffusion are applied to a base material 131 made of glass, thereby to afford a refractive index distribution and to configure a micro lens 132 of flat plate type. Besides, the micro lens 132 is formed at that part of the base material 131 which corresponds to a light emitting element 112, in a positioned state (in other words, at a part at which the optic axis of excitation light outputted from the light emitting element 112 is substantially in agreement with the optic axis of the micro lens 132), and the diameter of this micro lens 132 is made equal to or larger than the diameter (exit aperture) of the light emitting element 112.

In this manner, in accordance with the laser device 100 according to this embodiment, the setup of the device can be reduced in size, as in the first embodiment. Moreover, the loss of the excitation light can be decreased to heighten the output power of the device.

Besides, also in this embodiment, the longitudinal mode control of the excitation light is performed by the flat emission laser 110, so that the solid laser medium layer 121 can be directly excited between the energy levels of rare-earth ions or transition-metal ions with which this layer 121 is doped. Accordingly, the conversion efficiency of energy is high, and the output power can be heightened.

Besides, also in this embodiment, the light emission unit 120 includes a wavelength conversion layer 124 which generates the second harmonic of a peak wavelength, so that the device 100 is suitable as an RGB light source.

Further, in this embodiment, the lens member 130 is arranged on the output surface of the light emission unit 120, so that the beam shape of light which is outputted from the device 100 can be controlled.

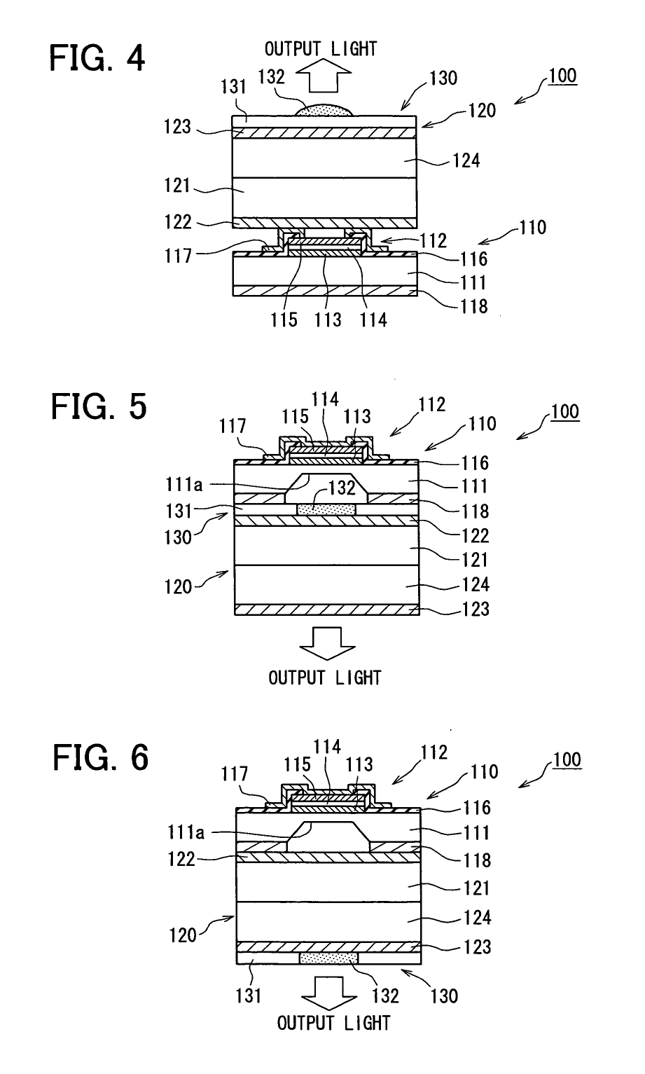

By the way, in this embodiment, the lens member 130 is stacked and arranged on the output surface of the light emission unit 120. Accordingly, in a case where nothing is arranged in touch with the output surface of the lens member 130, the lens member 130 including the flat plate type micro lens 132 need not be adopted as the lens member 130 because no problem is involved in the stacked structure. As shown in FIG. 4 by way of example, a lens member 130 including a micro lens 132 of convex type can be adopted. Incidentally, the convex type micro lens 132 can be configured by, for example, reflowing, ink jetting or gray scale masking. Also in this case, the beam shape of light which is outputted from a device 100 can be controlled as in the flat plate type. Moreover, the cost of the lens member 130 in the convex type can be made lower than in the flat plate type. FIG. 4 is a sectional view showing a modification to the second embodiment.

Besides, this embodiment has mentioned the example in which the lens member 130 is arranged on only the output surface of the light emission unit 120. It is also allowed, however, to adopt a configuration in which the configuration according to this embodiment is combined with the configuration according to the first embodiment (that is, the lens members 130 are respectively arranged on the excitation-light input surface and output surface of the light emission unit 120). In this case, both heightened output power and the beam shape control of the output light can be realized.

### Third Embodiment

Next, the third embodiment will be described in conjunction with FIG. 5. FIG. 5 is a sectional view showing the schematic configuration of a laser device 100 according to the third embodiment.

The laser device 100 according to the third embodiment is common to the laser device 100 illustrated in the first embodiment, at many parts.

As shown in FIG. 5, this embodiment features that a flat emission laser 110 is configured so as to output light onto the side of the opposite surface of a semiconductor substrate 111 to the surface thereof formed with a light emitting element 112 (onto the side of an n-type electrode 118), and that a light emission unit 120 and a lens member 130 are stacked and arranged on the opposite surface to the formation surface of the light emitting element 112.

Concretely, in the configuration illustrated in the first embodiment, the light emitting element 112 has its refractive index adjusted so that a first reflection layer 115 may become greater in reflection factor than a first reflection layer 113 with respect to the laser light (excitation light) which is outputted from an active layer 114. That is, the laser device 100 is configured so that the excitation light outputted from the active layer 114 may be resonated by the first reflection layers 113 and 115 and then lased onto the side of the first reflection layer 113.

Besides, the semiconductor substrate 111 is provided with a recess 111a which is open onto the side of the opposite surface to the formation surface of the light emitting element 112, in correspondence with the formation position of the light emitting element 112. Concretely, the recess 111a is formed in such a manner that the size of the bottom surface of this recess in the direction of the plane of the substrate 111 is larger than the diameter (exit aperture) of the light emitting element 112, and that the depth of this recess is as deep as possible, to the extent of exerting no influence on the light emitting element 112. Such a recess 111a can be configured by, for example, etching the semiconductor substrate 111. Besides, the n-type electrode 118 is formed on the opposite surface of the semiconductor substrate 111 to the light-emitting-element formation surface thereof, except the recess 111a.

In addition, the lens member 130 is stacked and arranged so as to be capable of condensing or collimating the beam of the excitation light, on the opposite surface of the flat emission laser 110 to the light-emitting-element formation surface thereof (on the surface formed with the n-type electrode 118). Thus, the light emission unit 120 is stacked and arranged on the flat emission laser 110 through the lens member 130.

In this manner, in accordance with the laser device 100 according to this embodiment, the setup of the device can be reduced in size, as in the first embodiment. Moreover, the loss of the excitation light can be decreased to heighten the output power of the device.

Besides, also in this embodiment, the longitudinal mode control of the excitation light is performed by the flat emission laser 110, so that the solid laser medium layer 121 can be directly excited between the energy levels of rare-earth ions or transition-metal ions with which this layer 121 is doped. Further, the lens member 130 is arranged between the output surface of the flat emission laser 110 and the excitation-light input surface of the light emission unit 120. Accordingly, the conversion efficiency of energy is high, and the output power can be heightened.

Besides, in this embodiment, neither of the light emission unit 120 nor the lens member 130 is stacked and arranged on the side of the light-emitting-element formation surface of the flat emission laser 110, and heat is easily radiated from the active layer 114. Accordingly, the output power can be heightened more. Incidentally, a thermal radiation property may well be enhanced more in such a way that a heat sink or the like heat radiation member is stacked and arranged on the light-emitting-element formation surface of the flat emission laser 110.

Besides, also in this embodiment, the light emission unit 120 includes a wavelength conversion layer 124 which generates the second harmonic of a peak wavelength, so that the device 100 is suitable as an RGB light source.

Incidentally, this embodiment has mentioned the example in which, in the configuration wherein the flat emission laser 110 outputs the excitation light through the semiconductor substrate 111, the recess 111a is formed in the semiconductor substrate 111. With such a configuration, that loss of the excitation light which is attributed to the fact that the excitation light is partly absorbed and attenuated by the semiconductor substrate 111 can be decreased to the utmost. It is also allowed, however, to adopt a configuration in which the recess 111a is not formed in the semiconductor substrate 111.

Besides, this embodiment has mentioned the example in which the lens member 130 is stacked and arranged between the flat emission laser 110 and the light emission unit 120. It is also possible, however, to adopt a configuration in which, as shown in FIG. 6, a lens member 130 is stacked and arranged on the output surface of a light emission unit 120. In this case, owing to the arrangement of the lens member 130 on the output surface of the light emission unit 120, the beam shape of light which is outputted from a device 100 can be controlled in the same manner as in the second embodiment. FIG. 6 is a sectional view showing a modification to the third embodiment. Incidentally, although a micro lens 132 of flat plate type has been shown in FIG. 6, a micro lens 132 of convex type can also be adopted as in the second embodiment.

Besides, it is also allowed to adopt a configuration in which the configuration according to this embodiment is combined with the configuration shown in FIG. 6 (that is, the lens members 130 are respectively arranged on the excitation-light input surface and output surface of the light emission unit 120). In this case, both heightened output power and the beam shape control of the output light can be realized.

### Fourth Embodiment

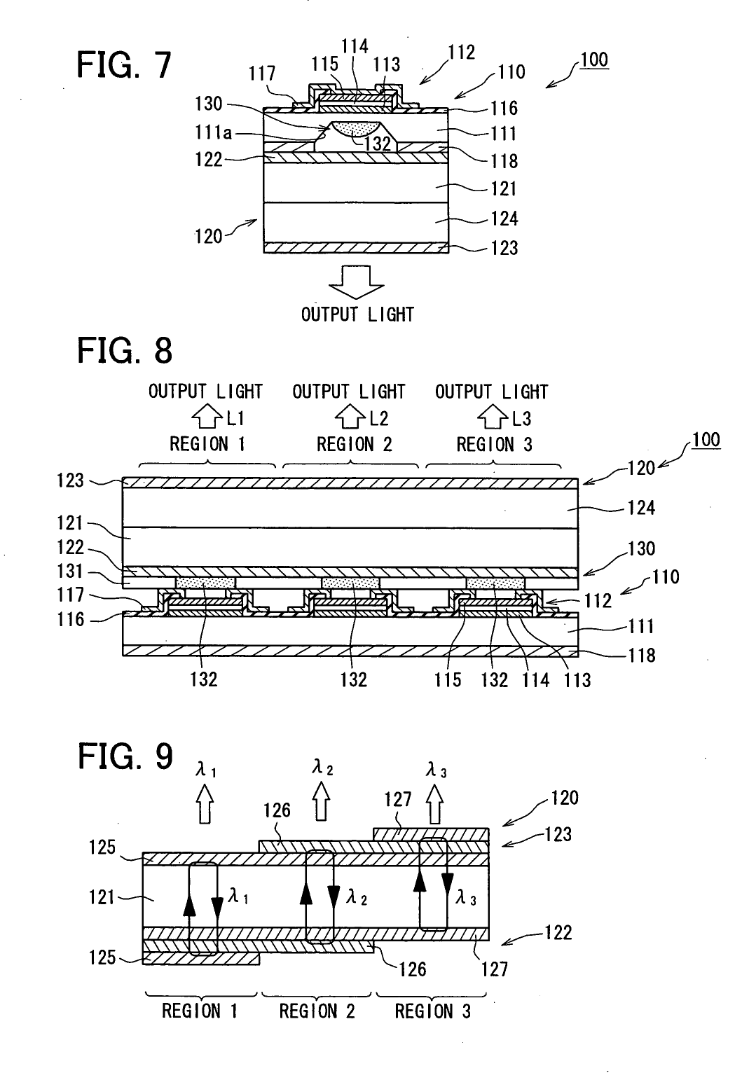

Next, the fourth embodiment will be described in conjunction with FIG. 7. FIG. 7 is a sectional view showing the schematic configuration of a laser device 100 according to the fourth embodiment.

The laser device 100 according to the fourth embodiment is common to the laser device 100 illustrated in the third embodiment, at many parts.

Also in this embodiment, as in the third embodiment, a flat emission laser 110 is configured so as to output light onto the side of the opposite surface of a semiconductor substrate 111 to the surface thereof formed with a light emitting element 112 (onto the side of an n-type electrode 118), and a light emission unit 120 and a lens member 130 are stacked and arranged on the opposite surface to the formation surface of the light emitting element 112. In addition, the semiconductor substrate 111 is provided with a recess 111a which is open onto the side of the opposite surface to the formation surface of the light emitting element 112, in correspondence with the formation position of the light emitting element 112. In such a configuration, this embodiment features that, as shown in FIG. 7, the lens member 130 is stacked and arranged on the bottom surface of the recess 111a.

Concretely, as the lens member 130, a micro lens 132 of convex type as has a diameter larger than the diameter (exit aperture) of the light emitting element 112 is formed in the recess 111a shown in the third embodiment, in such a manner that the micro lens 132 does not protrude from the recess 111a onto the opposite surface to the light-emitting-element formation surface of the semiconductor substrate 111 (namely, that the lens member 130 is accommodated in a space which is defined between the semiconductor substrate 111 and the light emission unit 120 by the recess 111a). By the way, in this embodiment, only the convex type micro lens 132 is employed as the lens member 130.

The lens member 130 as stated above can be configured in such a way that, after the formation of the recess 111a in the semiconductor substrate 111, the lens member 130 is located on the bottom surface of the recess 111a and then made unitary with the bottom surface by, for example, adhesion. In addition, after the arrangement of the lens member 130, the light emission unit 120 is stacked and arranged on the opposite surface to the light-emitting-element formation surface of the flat emission laser 110, whereby the laser device 100 in which the respective elements 110, 120 and 130 are stacked unitarily can be configured.

In this manner, in accordance with the laser device 100 according to this embodiment, the setup of the device 100 can be more reduced in size, in addition to the advantages of the laser device 100 illustrated in the third embodiment.

Besides, even in the case where the lens member 130 is stacked and arranged on the opposite surface of the semiconductor substrate 111, the distance between the light emitting element 112 (an active layer 114) and the micro lens 132 can be shortened, and hence, the efficiency of the collimation or condensation of the beam of the light can be enhanced. Accordingly, output power can be heightened more.

Besides, in spite of the configuration in which the lens member 130 is interposed between the flat emission laser 110 and the light emission unit 120, the lens member 130 is accommodated in the recess 111a, and hence, the convex type micro lens 132 can be adopted. Accordingly, the cost of manufacture can be lowered. Although the convex type micro lens 132 has been employed in this embodiment, a micro lens of flat plate type can also be adopted if no problem is involved in the cost of manufacture.

Incidentally, it is also allowed to adopt a configuration in which the configuration according to this embodiment is combined with the configuration according to the second embodiment (that is, the lens members 130 are respectively arranged on the excitation-light input surface and output surface of the light emission unit 120). In this case, both heightened output power and the beam shape control of output light can be realized.

### Fifth Embodiment

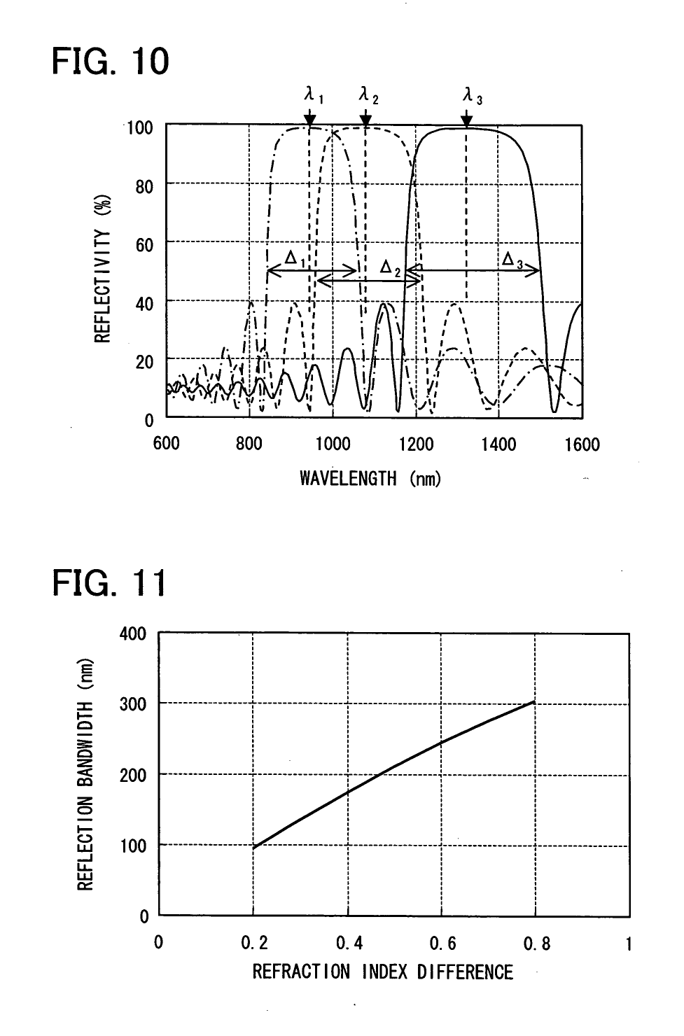

Next, the fifth embodiment will be described in conjunction with FIGS. 8-11. FIG. 8 is a sectional view showing the schematic configuration of a laser device 100 according to the fifth embodiment. FIG. 9 is an enlarged sectional view showing the configurations of second reflection layers 122 and 123. FIG. 10 is a diagram showing the reflection characteristics of a multilayer reflection film of Al₂O₃/TiO₂ in order to explain center wavelengths and reflection bandwidths. FIG. 11 is a diagram showing the relationship between a refractive index difference and the reflection bandwidth.

The laser device 100 according to the fifth embodiment is common to the laser device 100 illustrated in the first embodiment, at many parts.

The laser device 100 according to this embodiment has the first feature that the light emitting elements 112 of a flat emission laser 110 and the micro lenses 132 of a lens member 130 are arrayed. Besides, the laser device 100 has the second feature that, upon receiving excitation light, a solid laser medium layer 121 generates a plurality of lights having different peak wavelengths, and that a light emission unit 120 is divided into a plurality of regions by the configurations of the second reflection layers 122 and 123, the lights of the different peak wavelengths being resonated in the respective regions. In other words, the second feature is that the second reflection layers 122 and 123 are configured so as to be capable of outputting the plurality of lights having the different wavelengths, from the device 100.

The flat emission laser 110 according to this embodiment is configured in such a manner that the plurality of light emitting elements 112 each of which is shown in the first embodiment are arranged in one dimension (rectilinearly) or two dimensions (for example, in lattice fashion) on an identical semiconductor substrate 111. The configuration of each of the light emitting elements 112 is the same as in the first embodiment, and these elements 112 are arranged in the two dimensions so as to be spaced at equal intervals in the direction of the plane of the semiconductor substrate 111. Thus, the variance of a light intensity distribution is mitigated. Besides, the light emitting elements 112 are configured so as to be electrically controllable independently of one another. Concretely, as shown in FIG. 8, p-type electrodes 117 are insulatingly isolated for the respective light emitting elements 112.

The light emission unit 120 is configured in such a manner that the plurality of light emitting elements 112 are covered with the single solid laser medium layer 121. Also the lens member 130 is formed with the micro lenses 132 in a base material 131, in correspondence with the respective light emitting elements 112. Incidentally, the lens member 130 according to this embodiment is stacked and arranged between the light-emitting-element formation surface of the flat emission laser 110 and the excitation-light input surface of the light emission unit 120, and the micro lenses 132 of flat plate type are adopted.

In this manner, in accordance with the laser device 100 according to this embodiment, the respective elements 110, 120 and 130 are stacked and arranged, and they are joined unitarily. Accordingly, the output power of the device 100 can be heightened more while the setup thereof is reduced in size.

Next, there will be described the configurations of the second reflection layers 122 and 123 as form the second feature. Incidentally, the solid laser medium layer 121 is made of an Nd:YAG crystal as in the first embodiment. More specifically, the laser lights which have peak wavelengths λ₁, λ₂ and λ₃ within ranges of 900-950 nm (946 nm in this embodiment), 1040-1065 nm (1064 nm in this embodiment) and 1300-1350 nm (1319 nm in this embodiment) are respectively generated in accordance with the wavelength ko of the excitation light.

The second reflection layers 122 and 123 are divided into a plurality of regions by the differences of their configurations, and the respective regions resonate with the different peak wavelengths. The “configurations of the second reflection layers 122 and 123” signify at least one of, for example, constituent materials (refractive indices), thicknesses, and the numbers of stacked layers (cycles).

Each of the second reflection layers 122 and 123 according to this embodiment is formed of a multilayer reflection film of Al₂O₃/TiO₂ by a technique such as evaporation or sputtering, as in the first embodiment. As shown in FIG. 9, the second reflection layers 122 and 123 are divided into the three regions 1-3 so as to selectively resonate with the corresponding peak wavelengths. By the way, in this embodiment, the region 1 selectively resonates with the peak wavelength λ₁, the region 2 with the peak wavelength λ₂, and the region 3 with the peak wavelength λ₃.

Concretely, a reflection film for the peak wavelength λ₁, 125, a reflection film for the peak wavelength λ₂, 126 and a reflection film for the peak wavelength λ₃, 127 in which the thicknesses of individual layers constituting the multilayer reflection films of Al₂O₃/TiO₂ are respectively adjusted so as to afford high reflections at the peak wavelengths λ₁, λ₂ and λ₃ are stacked in any desired order from the side of the solid laser medium layer 121, on the output surface of this solid laser medium layer 121. In this embodiment, the reflection films are stacked in the order of the reflection film for the peak wavelength λ₁, 125, the reflection film for the peak wavelength λ₂, 126 and the reflection film for the peak wavelength λ₃, 127. Also on the excitation-light input surface of the solid laser medium layer 121, such reflection films are stacked in the reverse order to the order on the output surface, from the side of the solid laser medium layer 121. In this embodiment, the reflection films are stacked in the order of the reflection film for the peak wavelength λ₃, 127, the reflection film for the peak wavelength λ₂, 126 and the reflection film for the peak wavelength λ₁, 125. In addition, after the stacking operations, the unnecessary ones of the reflection films 125-127 are removed by photolithography and etching in each of the regions 1-3 so that the reflection films which afford the high reflections at the corresponding peak wavelength λ₁, λ₂ or λ₃ may become the outermost layers. More specifically, in the region 1, the reflection film for the peak wavelength λ₂, 126 and the reflection film for the peak wavelength λ₃, 127 on the output surface are removed so that the reflection films for the peak wavelength λ₁, 125 may become the outermost layers (namely, that they may form a pair). Besides, in the region 2, the reflection film for the peak wavelength λ₃, 127 on the output surface and the reflection film for the peak wavelength λ₁, 125 on the excitation-light input surface are removed so that the reflection films for the peak wavelength λ₂, 126 may become the outermost layers (namely, that they may form a pair). Further, in the region 3, the reflection film for the peak wavelength λ₁, 125 and the reflection film for the peak wavelength λ₂, 126 on the excitation-light input surface are removed so that the reflection films for the peak wavelength λ₃, 127 may become the outermost layers (namely, that they may form a pair).

In this embodiment, the thickness of each of the layers (Al₂O₃ layer and TiO₂ layer) constituting the reflection film 125, 126 or 127 is set at a value obtained by dividing the corresponding peak wavelength λ₁, λ₂ or λ₃ by the quadruple of the refractive index. Besides, the reflection factors of the respective reflection films 125-127 for the lights of the corresponding peak wavelengths λ₁, λ₂ and λ₃ are set so as to become lower in the second reflection layer 123 of output side than in the second reflection layer 122 of excitation-light input side. Accordingly, the respective regions 1-3 resonate with the corresponding peak wavelengths λ₁, λ₂ and λ₃, and the lights having the corresponding peak wavelengths λ₁, λ₂ and λ₃ are lased from the side of the second reflection layer 123.

However, in a case where the reflection bandwidth exhibiting the high reflection (for example, a wavelength width at a reflection factor of 50%) is broad in each of the reflection films 125-127 and where part of the reflection bandwidth includes the adjacent peak wavelength (that is, the center wavelength of the reflection bandwidth), the light of the adjacent peak wavelength is partly resonated together with the light of the corresponding peak wavelength. In other words, each of the reflection films 125-127 cannot be endowed with a sufficient wavelength selectivity. In this embodiment, therefore, as shown in FIG. 10, the reflection bandwidths Δ1 and Δ2 (or Δ2 and Δ3) which exhibit the high reflections in the reflection films 125 and 126 (or 126 and 127) corresponding to the adjacent peak wavelengths λ₁ and λ₂ (or λ₂ and λ₃), respectively, are set so as to satisfy |λ₁−λ₂|>Δ1/2, (or |λ₂−λ₃|>Δ2/2 and |λ₁−λ₂|>Δ2/2, (or |λ₂−λ₃|>3/2). Accordingly, the respective regions 1-3 can selectively resonate with the corresponding peak wavelengths λ₁, λ₂ and λ₃ and emits laser with these wavelengths.

Incidentally, the reflection bandwidths can be adjusted by the refractive indices (constituent materials) of the reflection films 125-127 as shown in FIG. 11 by way of example. That is, the materials which constitute the respective reflection films 125-127 may be properly selected. In this embodiment, the above relations are satisfied by employing the multilayer reflection films of Al₂O₃/TiO₂ (in case of, for example, λ₁: 946 nm and λ₂: 1064 nm, a refractive index difference of at most 0.57 is set so that the reflection bandwidths Δ1 and Δ2 may become 236 nm or less). In other words, resonators which selectively resonate with the peak wavelengths λ₁, λ₂ and λ₃ are configured within the identical plane of the light emission unit 120.

In this manner, in accordance with the laser device 100 according to this embodiment, the solid laser medium layer 121 adopted generates the plurality of different peak wavelengths by receiving the excitation light of the single wavelength, and the configurations of the second reflection layers 122 and 123 are made different for the respective regions 1-3, whereby the respective regions 1-3 selectively resonate with the corresponding peak wavelengths λ₁, λ₂ and λ₃ and emits the laser with these wavelengths. Accordingly, the laser device 100 is capable of simultaneously outputting the plurality of lights of the different wavelengths by using as the excitation light, that light of the single wavelength which is outputted from the flat emission laser 110.

Besides, the resonators which selectively resonate with the different peak wavelengths λ₁, λ₂ and λ₃ are configured within the identical plane of the light emission unit 120. Accordingly, the setup of the device 100 can be reduced in size in spite of the configuration capable of simultaneously outputting the plurality of lights of the different wavelengths.

Besides, also in this embodiment, the longitudinal mode control of the excitation light is performed by the flat emission laser 110, so that the solid laser medium layer 121 can be directly excited between the energy levels of rare-earth ions or transition-metal ions with which this layer 121 is doped. Further, the lens member 130 in which the micro lenses 132 are arrayed in correspondence with the light emitting elements 112 is arranged between the output surface of the flat emission laser 110 and the excitation-light input surface of the light emission unit 120. Accordingly, the output lights L1, L2 and L3 can be heightened in power.

Besides, in the laser device 100 according to this embodiment, a wavelength conversion layer 124 made of a nonlinear crystal is included in the light emission unit 120, as in the first embodiment. Concretely, the wavelength conversion layer 124 is made of KTP, and it is stacked and arranged between the solid laser medium layer 121 and the second reflection film 123 of the output side as shown in FIG. 8. Accordingly, the lights which are generated from Nd ions, which are selectively resonated and lased by the second reflection layers 122 and 123 and which have the peak wavelengths λ₁, λ₂ and λ₃ within the respective ranges of 900-950 nm, 1040-1065 nm and 1300-1350 nm in a near-infrared region, can be converted into the lights L1, L2 and L3 which have wavelengths within respective ranges of 450-475 nm, 520-533 nm and 650-675 nm in a visible light region. That is, the plurality of lights L1, L2 and L3 having respective colors R, G and B can be simultaneously outputted from within the identical plane of the single device 100. Accordingly, the laser device 100 is suitable as a light source for RGB use.

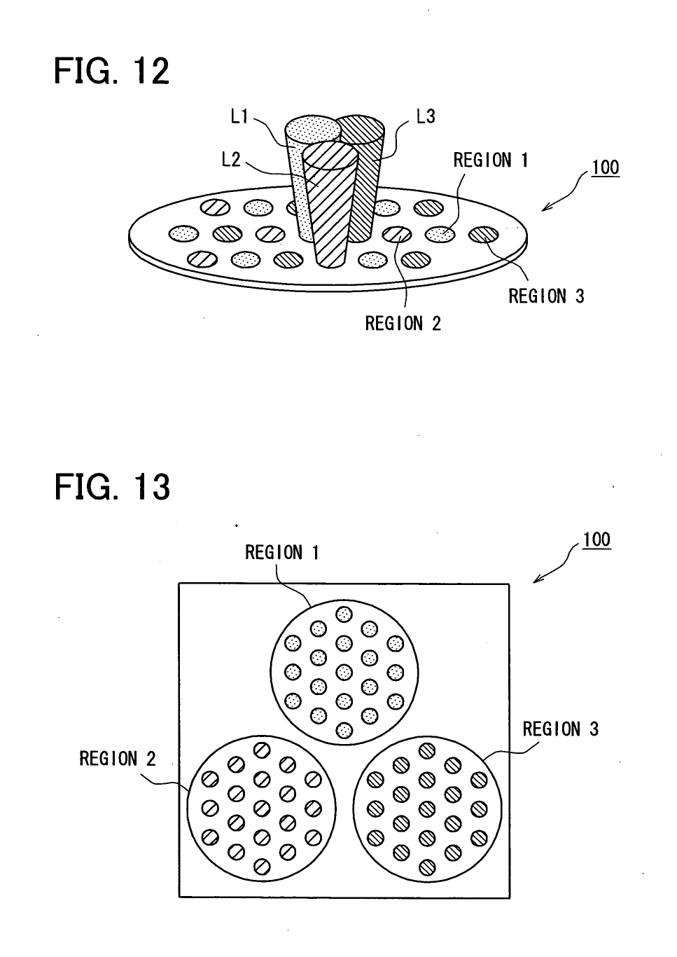

Incidentally, the arrangement of the regions 1-3 which output the plurality of lights L1, L2 and L3 having the respective colors R, G and B is not especially restricted. The regions 1-3 may be arranged regularly, or may well be arranged at random. By way of example, as shown in FIG. 12, the regions 1-3 for outputting the lights L1, L2 and L3 of the different wavelengths may be disposed so as to adjoin one another (in other words, so that every three regions 1-3 may form one group). Alternatively, as shown in FIG. 13, each of the individual regions 1-3 may be disposed so as to receive excitation lights from a plurality of light emitting elements 112. In this case, the power of each of the respective laser lights L1, L2 and L3 can be made higher than in the configuration shown in FIG. 12. By the way, in accordance with the laser characteristics and visibilities of the lights L1, L2 and L3 which are outputted from the respective regions 1-3, it is possible to properly set the numbers of the light emitting elements 112, the exit apertures (diameters), the intervals between the elements, etc. in correspondence with the respective regions 1-3. FIGS. 12 and 13 are model diagrams each showing the setting example of the regions 1-3. Needless to say, although the laser lights L1, L2 and L3 in only one group are outputted for the sake of outward appearance in FIG. 12, the corresponding laser lights L1, L2 and L3 can be similarly outputted from the remaining groups of the regions 1-3.

Besides, this embodiment has mentioned the example in which the regions 1-3 selectively resonating with the respective peak wavelengths λ₁, λ₂ and λ₃ are configured by the thicknesses of the reflection films 125-127 constituting the second reflection layers 122 and 123 (the thicknesses of the Al₂O₃ layer and the TiO₂ layer which constitute each of the reflection films 125-127). The regions 1-3, however, may well be configured by changing the constituent materials (refractive indices) of the second reflection layers 122 and 123 or the numbers of stacked layers (cycles).

Besides, this embodiment has mentioned the example in which the second reflection layers 122 and 123 are configured by collectively stacking the reflection films 125-127 for the respective regions 1-3 and subsequently removing the unnecessary parts of the reflection films so as to form only the pairs of the reflection films necessary for the respective regions 1-3. When the second reflection layers 122 and 123 are configured in this way, the manufacturing process thereof can be simplified. However, the second reflection layers 122 and 123 may well be configured in such a way that only the reflection film for the wavelength λ₁, 125, the reflection film for the wavelength λ₂, 126 and the reflection film for the wavelength λ₃, 127 are respectively formed selectively for the regions 1-3 by photolithography. In this case, the second reflection layers 122 and 123 can be flattened more than in the example mentioned in this embodiment.

Besides, this embodiment has mentioned the example in which the light emission unit 120 includes the wavelength conversion layer 124. It is also allowed, however, to adopt a configuration in which the wavelength conversion layer 124 is not included.

Besides, this embodiment has mentioned the example in which the configurations of the second reflection films 122 and 123 differ in the respective regions 1-3. However, the number of regions is not restricted to three. By way of example, the two reflection layers 122 and 123 may well be configured so as to output only the lights of two colors among the plurality of lights L1, L2 and L3 having the colors R, G and B. Alternatively, the configurations of the second reflection films 122 and 123 may well be identical in the respective regions. In this manner, the second reflection layers 122 and 123 are configured so as to resonate with one peak wavelength, whereby the output power of the light (laser light) having the single wavelength can be heightened in the configuration including the flat emission laser 110 in which the light emitting elements 112 are arrayed.

Besides, this embodiment has mentioned the example in which the light emitting elements 112 are configured so as to be drivable and controllable independently of one another (that is, in which the p-type electrodes 117 are insulatingly isolated for the respective elements). Accordingly, the intensities of the lights L1, L2 and L3 which are outputted from the respectively corresponding regions 1-3 can be individually adjusted in such a way that the light emission timings (ON/OFF operations or light-emission time periods) of the light emitting elements 112 are controlled by light-emission control means (not shown).

Besides, in the case where, as shown in FIG. 13, each of the regions 1-3 is configured so as to receive the excitation lights from the plurality of light emitting elements 112, the intensities of the individual colors can be adjusted in such a way that the numbers of times of the light emissions of the light emitting elements 112 (that is, the light-emission ON/OFF operations of the light emitting elements 112) are controlled in the respective regions 1-3. Further, in case of synthesizing the individual colors, the intensities and color tones of synthetic lights can be adjusted. Incidentally, similar advantages can be expected by controlling the light-emission time periods. It is also allowed to adopt a configuration in which the numbers of times of the light emissions and the light-emission time periods are both controlled. In the configuration shown in FIG. 13, the plurality of light emitting elements 112 corresponding to each of the regions 1-3 may well be electrically connected in parallel. Thus, a control system which controls the light emission timings (ON/OFF operations or light-emission time periods) of the light emitting elements 112 can be simplified.

Incidentally, a control method based on the light-emission control means is not especially restricted. It is also allowed to adopt, for example, a configuration in which the light-emission control means controls the light emission timings of the light emitting elements 112 so as to hold desired intensities or color tones, on the basis of a signal from a sensor that measures a physical quantity (for example, a sensor that detects the light outputted from the device 100). Besides, the light emission timings of the light emitting elements 112 may well be controlled in accordance with a prestored program.

### Sixth Embodiment

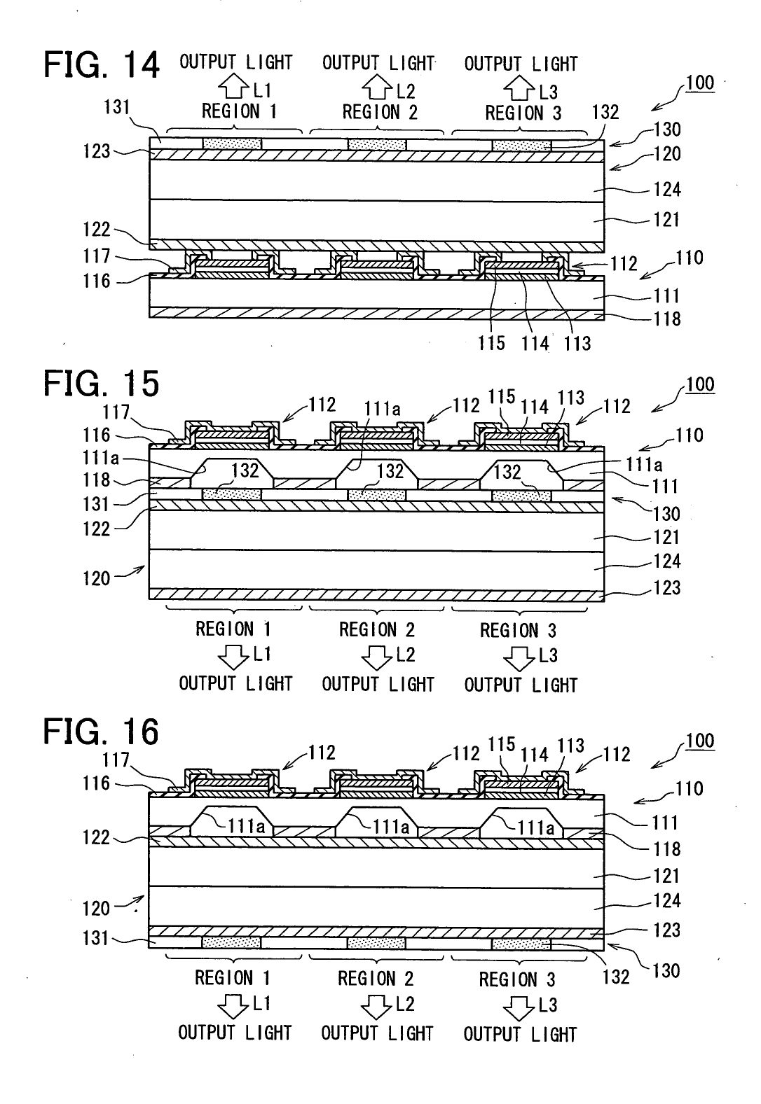

Next, the sixth embodiment will be described in conjunction with FIG. 14. FIG. 14 is a sectional view showing the schematic configuration of a laser device 100 according to the sixth embodiment.

The laser device 100 according to the sixth embodiment is common to the laser devices 100 illustrated in the second and fifth embodiments, at many parts.

As shown in FIG. 14, the laser device 100 according to this embodiment features that the arrangement structure of the lens member 130 illustrated in the second embodiment is combined with the array structure illustrated in the fifth embodiment.

In this manner, also in the laser device 100 according to this embodiment, light of single wavelength as is outputted from a flat emission laser 110 is used as excitation light, and a plurality of lights of different wavelengths can be simultaneously outputted, as in the fifth embodiment.

Besides, also in this embodiment, resonators which selectively resonate with the different peak wavelengths λ₁, λ₂ and λ₃ are configured within the identical plane of a light emission unit 120. Accordingly, the setup of the device 100 can be reduced in size in spite of the configuration capable of simultaneously outputting the plurality of lights of the different wavelengths.

Besides, also in this embodiment, the longitudinal mode control of the excitation light is performed by the flat emission laser 110, so that a solid laser medium layer 121 can be directly excited between the energy levels of rare-earth ions or transition-metal ions with which this layer 121 is doped. Accordingly, the conversion efficiency of energy is high, and output power can be heightened.

Besides, also in this embodiment, a wavelength conversion layer 124 made of a nonlinear crystal is included in the light emission unit 120. Accordingly, the excitation light can be converted into lights L1, L2 and L3 which have wavelengths within respective ranges of 450-475 nm, 520-533 nm and 650-675 nm in a visible light region. That is, the plurality of lights L1, L2 and L3 having respective colors R, G and B can be simultaneously outputted from within the identical plane of the single device 100. Accordingly, the laser device 100 is suitable as a light source for RGB use.

Besides, in this embodiment, the lens member 130 in which micro lenses 132 are arrayed in correspondence with light emitting elements 112 is arranged on the output surface of the light emitting unit 120. Accordingly, the beam shapes of the output lights L1, L2 and L3 can be controlled by the micro lenses 132. By the way, in this embodiment, all of the micro lenses 132 are configured so as to have the same refractive index distributions, by ion diffusion. In the plurality of micro lenses 132, however, at least any of the diffractive index distributions may well differ from the others.

Incidentally, it is also allowed to adopt a configuration in which the configuration according to this embodiment is combined with the configuration according to the fifth embodiment (that is, the lens members 130 are respectively arranged on the excitation-light input surface and output surface of the light emission unit 120). In this case, both heightened output power and the beam shape controls of the output lights can be realized.

Besides, in this embodiment, as shown in FIG. 14, the micro lenses 132 of flat plate type are adopted as the lens member 130. However, in a case where nothing is stacked and arranged on the output surface of the lens member 130, the micro lenses 132 of convex type as stated before (refer to FIG. 4) can also be adopted.

### Seventh Embodiment

Next, the seventh embodiment will be described in conjunction with FIG. 15. FIG. 15 is a sectional view showing the schematic configuration of a laser device 100 according to the seventh embodiment.

The laser device 100 according to the seventh embodiment is common to the laser devices 100 illustrated in the third and fifth embodiments, at many parts.

As shown in FIG. 15, the laser device 100 according to this embodiment features that the arrangement structure of the lens member 130 illustrated in the third embodiment is combined with the array structure illustrated in the fifth embodiment. By the way, in the seventh embodiment, a semiconductor substrate 111 is formed with a recess 111a in correspondence with each light emitting element 112, as in the third embodiment.

In this manner, also in the laser device 100 according to this embodiment, light of single wavelength as is outputted from a flat emission laser 110 is used as excitation light, and a plurality of lights of different wavelengths can be simultaneously outputted.

Besides, also in this embodiment, resonators which selectively resonate with the different peak wavelengths λ₁, λ₂ and λ₃ are configured within the identical plane of a light emission unit 120. Accordingly, the setup of the device 100 can be reduced in size in spite of the configuration capable of simultaneously outputting the plurality of lights of the different wavelengths.

Besides, also in this embodiment, the longitudinal mode control of the excitation light is performed by the flat emission laser 110, so that a solid laser medium layer 121 can be directly excited between the energy levels of rare-earth ions or transition-metal ions with which this layer 121 is doped. Further, the lens member 130 in which micro lenses 132 are respectively arrayed in correspondence with the light emitting elements 112 is arranged between the output surface of the flat emission laser 110 and the excitation-light input surface of the light emission unit 120. Accordingly, output lights L1, L2 and L3 can be heightened in power.

Besides, also in this embodiment, a wavelength conversion layer 124 made of a nonlinear crystal is included in the light emission unit 120. Accordingly, the excitation light can be converted into the lights L1, L2 and L3 which have wavelengths within respective ranges of 450-475 nm, 520-533 nm and 650-675 nm in a visible light region. That is, the plurality of lights L1, L2 and L3 having respective colors R, G and B can be simultaneously outputted from within the identical plane of the single device 100. Accordingly, the laser device 100 is suitable as a light source for RGB use.

Besides, in this embodiment, neither of the light emission unit 120 nor the lens member 130 is stacked and arranged on the side of the light-emitting-element formation surface of the flat emission laser 110, and heat is easily radiated from active layers 114. Accordingly, the output power can be heightened more. Incidentally, a thermal radiation property may well be enhanced more in such a way that a heat sink or the like heat radiation member is stacked and arranged on the light-emitting-element formation surface of the flat emission laser 110.

Incidentally, this embodiment has mentioned the example in which, in the configuration wherein the flat emission laser 110 outputs the excitation light through the semiconductor substrate 111, the semiconductor substrate 111 is formed with the recesses 111a in correspondence with the respective light emitting elements 112. With such a configuration, that loss of the excitation light which is attributed to the fact that the excitation light is partly absorbed and attenuated by the semiconductor substrate 111 can be decreased to the utmost. It is also allowed, however, to adopt a configuration in which the recesses 111a are not formed in the semiconductor substrate 111.

Besides, this embodiment has mentioned the example in which the lens member 130 is stacked and arranged between the flat emission laser 110 and the light emission unit 120. It is also possible, however, to adopt a configuration in which, as shown in FIG. 16, a lens member 130 is stacked and arranged on the output surface of a light emission unit 120. In this case, owing to the arrangement of the lens member 130 on the output surface of the light emission unit 120, the beam shapes of lights which are outputted from a device 100 can be controlled in the same manner as in the sixth embodiment. FIG. 16 is a sectional view showing a modification to the seventh embodiment. Incidentally, although micro lenses 132 of flat plate type have been shown in FIG. 16, micro lenses 132 of convex type can also be adopted.

Besides, it is also allowed to adopt a configuration in which the configuration according to this embodiment is combined with the configuration shown in FIG. 16 (that is, the lens members 130 are respectively arranged on the excitation-light input surface and output surface of the light emission unit 120). In this case, both heightened output power and the beam shape controls of the output lights can be realized.

### Eighth Embodiment

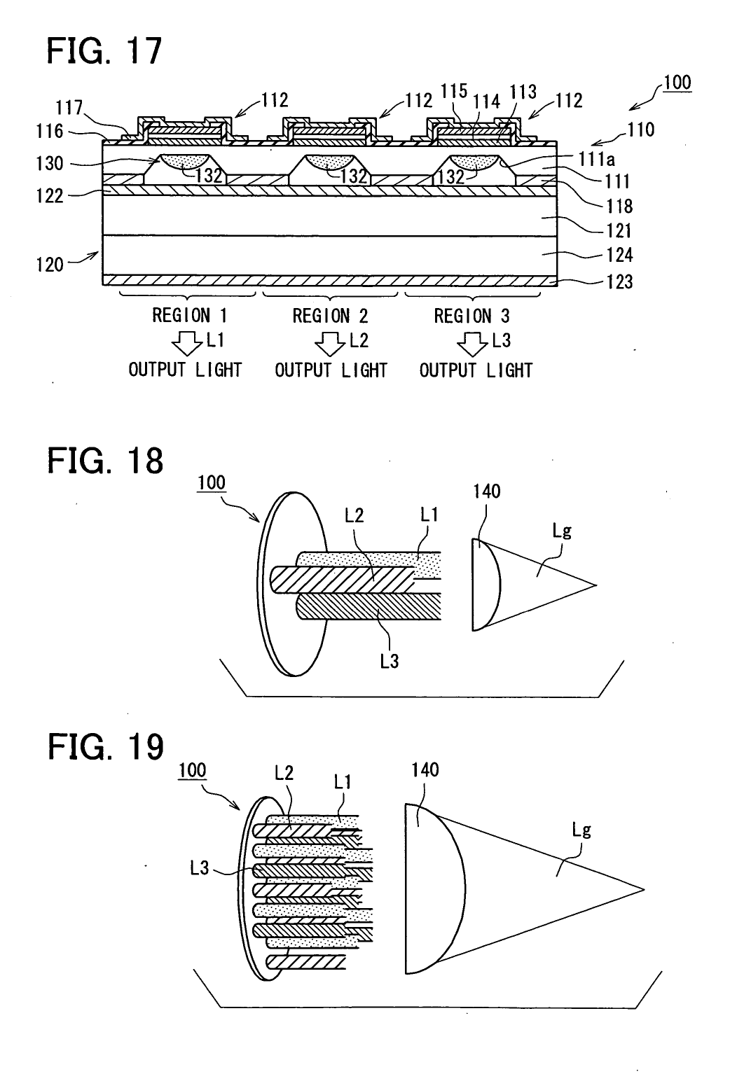

Next, the eighth embodiment will be described in conjunction with FIG. 17. FIG. 17 is a sectional view showing the schematic configuration of a laser device 100 according to the eighth embodiment.

The laser device 100 according to the eighth embodiment is common to the laser devices 100 illustrated in the fourth and fifth embodiments, at many parts.

As shown in FIG. 17, the laser device 100 according to this embodiment features that the arrangement structure of the lens member 130 illustrated in the fourth embodiment is combined with the array structure illustrated in the fifth embodiment. By the way, in the eighth embodiment, the lens member 130 is configured of micro lenses 132 of convex type, as in the fourth embodiment.

In this manner, in accordance with the laser device 100 according to this embodiment, the lens member 130 is accommodated in a space which is defined between a semiconductor substrate 111 and a light emission unit 120 by recesses 111a. Therefore, the laser device 100 can reduce the size of its setup still further, in addition to the advantages of the laser device 100 illustrated in the seventh embodiment.

Besides, even in the case where the lens member 130 is stacked and arranged on the opposite surface of the semiconductor substrate 111 to the surface thereof formed with light emitting elements 112, the distance between each of the light emitting elements 112 (active layers 114) and the corresponding micro lens 132 can be shortened, so that the efficiency of the collimation or condensation of excitation light can be enhanced. Accordingly, output power can be heightened more.

Besides, in spite of the configuration in which the lens member 130 is interposed between a flat emission laser 110 and the light emission unit 120, the lens member 130 is accommodated in the recesses 111a, and hence, the convex type micro lenses 132 can be adopted. Accordingly, the cost of manufacture can be lowered. Although the convex type micro lenses 132 have been employed in this embodiment, micro lenses of flat plate type can be adopted if no problem is involved in the cost of manufacture.

Incidentally, it is also allowed to adopt a configuration in which the configuration according to this embodiment is combined with the configuration according to the sixth embodiment (that is, the lens members 130 are respectively arranged on the excitation-light input surface and output surface of the light emission unit 120). In this case, both heightened output power and the beam shape controls of output lights can be realized.

### Ninth Embodiment

Next, the ninth embodiment will be described in conjunction with FIG. 18. FIG. 18 is a sectional view showing the schematic configuration of a laser device 100 according to the ninth embodiment.

The laser device 100 according to the ninth embodiment is common to the laser devices 100 illustrated in the fifth-eighth embodiments, at many parts.

As shown in FIG. 18, the laser device 100 according to this embodiment features that it includes a synthesis member 140 which is arranged on the output surface of a light emission unit 120, and which generates synthetic light by collecting a plurality of laser lights that are outputted from the light emission unit 120 and that correspond to respective light emitting elements 112.

The synthesis member 140 is not especially restricted as long as it can generate the synthetic light. In this embodiment, a condensing lens is adopted as the synthesis member 140. By the way, a configuration in FIG. 18 is such that, in the configuration of FIG. 12 as illustrated in the fifth embodiment, the synthesis member 140 is arranged so as to cover each of the regions 1-3. That is, the synthetic light Lg is generated including each of the laser lights L1, L2 and L3. Accordingly, in the case where the respective laser lights L1, L2 and L3 correspond to the colors R, G and B as illustrated in the fifth embodiment, respectively, a full-color synthetic beam can be obtained by changing the intensities of the respective laser lights L1, L2 and L3.

Besides, it is favorable to synthesize the laser lights L1, L2 and L3 by the synthesis member 140 in the state where, as illustrated in the foregoing embodiment, the lens member 130 is arranged on the output surface of the light emission unit 120, thereby to collimate the respective laser lights L1, L2 and L3 into parallel lights. In this case, the synthetic light can be efficiently generated.

Incidentally, this embodiment has mentioned the example in which the condensing lens is adopted as the synthesis member 140. The synthesis member 140, however, is not restricted to the condensing lens.

Besides, this embodiment has mentioned the example in which the synthesis member 140 is arranged so as to cover each of the regions 1-3. It is also possible, however, to adopt a configuration in which, as shown in FIG. 19, the synthesis member 140 is arranged so as to cover a plurality of regional groups each consisting of the regions 1-3. That is, the synthetic light Lg may well include the plurality of laser lights L1, laser lights L2 and laser lights L3. In this case, the output power of the synthetic light Lg can be heightened more than in the configuration shown in FIG. 18.

Besides, it is also possible to adopt a configuration in which the synthesis member 140 is arranged so as to cover only two of the regions 1-3. Also in this case, the synthetic light Lg becomes light in which lights of different wavelengths are synthesized, and a synthetic beam of high power having, for example, a predetermined color can be obtained.

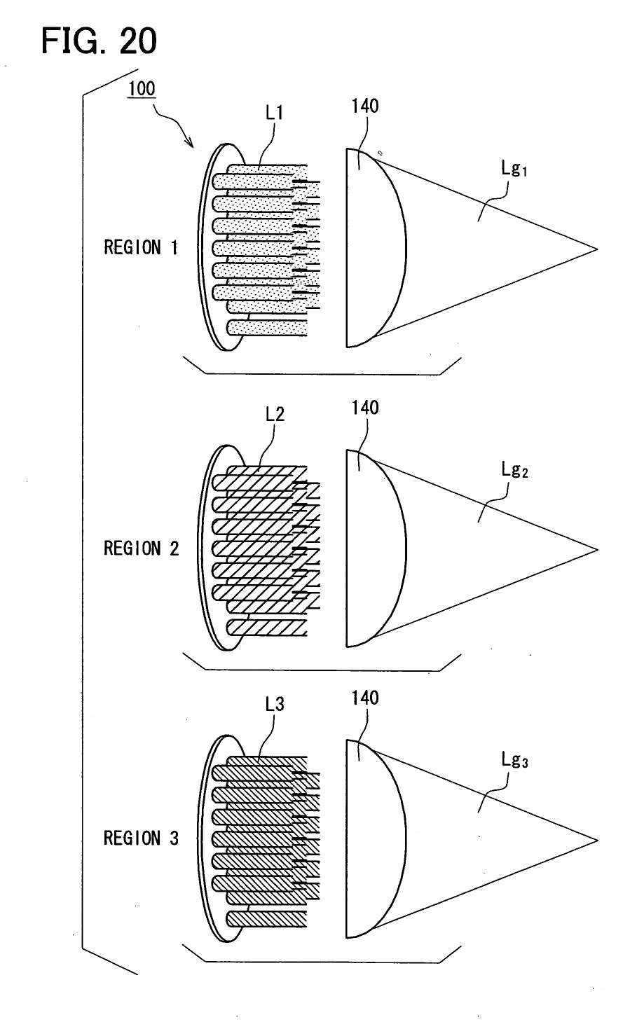

Besides, it is possible to adopt a configuration in which, as shown in FIG. 20, synthesis members 140 are arranged for the respective regions 1-3. In this case, each of synthetic lights Lg₁-Lg₃ becomes laser light of single wavelength, and the laser light of high output power can be obtained. By the way, in the case where the synthesis members 140 generate the plurality of different synthetic lights, for example, the synthetic lights Lg₁-Lg₃ shown in FIG. 20, they are unitarily configured likewise to the lens member 130, whereby they can be collectively positioned, and the setup of a laser device 100 can be reduced in size still further.

By the way, in the case where the lights of the different wavelengths are synthesized into the synthetic light Lg, the intensity and color tone of the synthetic light can be adjusted by controlling the number of light emissions of the light emitting elements 112 (that is, the light-emission ON/OFF operations of the individual light emitting elements 112) in the respective regions 1-3. Besides, in the case where the lights of the identical wavelength are synthesized into the synthetic light Lg, a laser characteristic (light emission intensity) can be adjusted by controlling the number of light emissions of the light emitting elements 112. In a case, for example, where the synthetic light Lg is visible light, it can be adjusted in accordance with a visibility. Incidentally, similar advantages can also be expected by controlling light-emission time periods. It is also allowed to adopt a configuration in which both the number of light emissions and the light-emission time periods are controlled.

Besides, in the configuration shown in FIG. 20, the plurality of light emitting elements 112 corresponding to each of the regions 1-3 may well be electrically connected in parallel. Thus, a control system which controls the light emission timings (ON/OFF operations or light-emission time periods) of the light emitting elements 112 can be simplified.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A laser equipment comprising:
a surface emitting laser for emitting an excitation light, wherein the surface emitting laser includes a pair of first reflection layers and an activation layer disposed between the pair of first reflection layers;
a light converter for outputting an output light by receiving the excitation light, wherein the output light has a peak wavelength, which is different from a peak wavelength of the excitation light, and wherein the light converter includes a pair of second reflection layers and a solid laser medium layer disposed between the pair of second reflection layers; and
a lens portion for collimating or concentrating a light, wherein
the surface emitting laser has an emitting surface for emitting the excitation light, and the light converter has an input surface for receiving the excitation light and an output surface for outputting the output light, and
the surface emitting laser, the light converter and the lens portion are integrally stacked so that the lens portion is disposed between the emitting surface of the surface emitting laser and the input surface of the light converter or disposed on the output surface of the light converter.

2. The equipment according to claim 1, wherein
the surface emitting laser further includes a semiconductor substrate having a foreside and a backside,
the pair of first reflection layers with the activation layer is disposed on the foreside of the semiconductor substrate, and
each first reflection layer has a different reflectivity, which is determined to emit the excitation light toward a direction opposite to the semiconductor substrate.

3. The equipment according to claim 1, wherein
the surface emitting laser further includes a semiconductor substrate having a foreside and a backside,
the pair of first reflection layers with the activation layer is disposed on the foreside of the semiconductor substrate, and
each first reflection layer has a different reflectivity, which is determined to emit the excitation light toward the semiconductor substrate.

4. The equipment according to claim 3, wherein
the lens portion is disposed between the emitting surface of the surface emitting laser and the input surface of the light converter, and
the lens portion includes a planar micro lens.

5. The equipment according to claim 3, wherein
the semiconductor substrate includes a groove, and
the groove is disposed on the backside of the substrate at a predetermined position corresponding to the pair of first reflection layers with the activation layer.

6. The equipment according to claim 5, wherein
the lens portion is disposed on a bottom of the groove.

7. The equipment according to claim 6, wherein
the lens portion includes a planar micro lens or a convex micro lens.

8. The equipment according to claim 2, wherein
the lens portion is disposed on the output surface of the light converter, and
the lens portion includes a planar micro lens or a convex micro lens.

9. The equipment according to claim 3, wherein
the lens portion is disposed on the output surface of the light converter, and
the lens portion includes a planar micro lens or a convex micro lens.

10. The equipment according to claim 1, wherein
the pair of first reflection layers with the activation layer provides a light emitting element, and
the lens portion includes a micro lens having a diameter, which is equal to or larger than a diameter of the light emitting element.

11. The equipment according to claim 1, wherein
the light converter further includes a wavelength converting layer, which is disposed between the solid laser medium layer and the output surface of the light converter, and
the wavelength converting layer converts the peak wavelength of the excitation light.

12. The equipment according to claim 11, wherein
the wavelength converting layer is made of non-linear crystal for generating a second harmonic light of the peak wavelength of the excitation light.

13. The equipment according to claim 1, wherein
the pair of first reflection layers with the activation layer provides a light emitting element, and
the lens portion includes a micro lens, which corresponds to the light emitting element.

14. The equipment according to claim 13, wherein
the pair of second reflection layers is capable of resonating at the peak wavelength of the output light.

15. The equipment according to claim 1, further comprising:
a plurality of surface emitting lasers for emitting excitation lights, individually, wherein each surface emitting laser includes a pair of first reflection layers and an activation layer; and
a plurality of lens portions for collimating or concentrating a light, wherein
the pair of first reflection layers and the activation layer in each surface emitting laser provide a light emitting element,
each lens portion includes a micro lens, which corresponds to the light emitting element,
the light emitting elements are integrated together so that a light emitting element array is provided, and
the micro lenses are integrated together so that a micro lens array is provided.

16. The equipment according to claim 15, further comprising:
a semiconductor substrate, and
the light emitting elements are arranged on the semiconductor substrate to be a predetermined two dimensional arrangement.

17. The equipment according to claim 16, wherein
the light emitting elements are arranged at even intervals on the semiconductor substrate.

18. The equipment according to claim 15, wherein
the pair of second reflection layers is capable of resonating at one of peak wavelengths of output lights.

19. The equipment according to claim 18, further comprising:
a combining system for combining the output lights outputted from the light converter into a combined light, wherein
the combining system is disposed on the lens portion or the output surface of the light converter.

20. The equipment according to claim 19, wherein
the combining system is a condenser lens.

21. The equipment according to claim 15, wherein
the solid laser medium layer receives the excitation lights from the light emitting elements, and outputs output lights, each of which corresponds to the excitation light,
the pair of second reflection layers with the solid laser medium layer includes a plurality of regions, and
the regions are capable of resonating at different peak wavelengths of the output lights, respectively, so that the output lights have different peak wavelengths, respectively.

22. The equipment according to claim 21, wherein
the pair of second reflection layers includes an output side second reflection layer and an input side second reflection layer,
the output side second reflection layer includes a plurality of reflection films, each of which has a maximum reflectivity at the peak wavelength of the corresponding output light,
the reflection films in the output side second reflection layer are stacked on the solid laser medium layer in a predetermined output side order of peak wavelengths,
the input side second reflection layer includes a plurality of reflection films, each of which has a maximum reflectivity at the peak wavelength of the corresponding output light,
the reflection films in the input side second reflection layer are stacked on the solid laser medium layer in an input side order of peak wavelengths, which is opposite to the output side order, and
an utmost outer reflection film of the stacked reflection films of the output side second reflection layer in each resonator region has a maximum reflectivity at a peak wavelength of the corresponding output light of the resonator region, the peak wavelength of which is equal to a peak wavelength of an utmost outer reflection film of the stacked reflection films of the input side second reflection layer in the resonator region.

23. The equipment according to claim 22, wherein
each reflection film includes two different refraction index layers,
each different refraction index layer has a thickness, a refraction index, and a corresponding peak wavelength of the output light, and
the thickness of one different refraction index layer in one of the reflection films is equal to the corresponding peak wavelength divided by four times of the refraction index.

24. The equipment according to claim 22, wherein
one of the reflection films has a corresponding peak wavelength of the output light defined as λ1 and a reflection bandwidth defined as Δ1,
another one of the reflection films has another corresponding peak wavelength of the output light defined as λ2 and another reflection bandwidth defined as Δ2,
the peak wavelengths of λ1 and λ2 and the reflection bandwidths of Δ1 and Δ2 satisfy relationships of |λ₁−λ₂|>Δ1/2 and |λ₁−λ₂|>Δ2/2.

25. The equipment according to claim 21, further comprising:
a combining system for combining output lights outputted from the light converter into a combined light, wherein
the combining system is disposed on the lens portion or the output surface of the light converter.

26. The equipment according to claim 25, wherein
the combining system is a condenser lens.

27. The equipment according to claim 25, wherein
the output lights to be combined by the combining system have a same peak wavelength.

28. The equipment according to claim 25, wherein
the output lights to be combined by the combining system include at least two peak wavelengths.

29. The equipment according to claim 25, wherein
each region is capable of receiving a plurality of the excitation lights from the corresponding light emitting elements,
the combining system includes a plurality of combining elements, and
each combining element combines the output lights outputted from the corresponding region.

30. The equipment according to claim 29, wherein
the light emitting elements corresponding to one region are electrically connected in parallel to one another.

31. The equipment according to claim 30, wherein
the light emitting elements corresponding to one region are integrally controlled to be independent from other light emitting elements corresponding to another region.

32. The equipment according to claim 15, wherein
each light emitting element is controlled independently from one another.
